(19) United States
(12) Patent Application Publication
(10) Pub. No.: US 2026/0324054 A1
(43) Pub. Date: Oct. 15, 2026

(54) INTEGRATED PLANAR MOSFET AND TRENCH SCHOTTKY BARRIER DIODE AND METHODS TO MANUFACTURE SAME

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/392,309

(22) Filed: Nov. 18, 2025

Related U.S. Application Data
(60) Provisional application No. 63/730,292, filed on Dec. 10, 2024.

(51) Int. Cl. H10D 84/00; H10D 8/01

(52) U.S. Cl. CPC H10D 84/146; H10D 8/051

(57) ABSTRACT

An apparatus including a planar metal oxide semiconductor field-effect transistor and a trench Schottky barrier diode that are physically and functionally integrated into a single, continuous structure, and a method of making such an apparatus. The integrated, trench Schottky barrier diode is located over a junction field-effect transistor neck region which is adjacent to the planar metal oxide semiconductor field-effect transistor. The Schottky barrier diode and the planar metal oxide semiconductor field-effect transistor may be located in a single, continuous volume of semiconductor material. The planar metal oxide semiconductor field-effect transistor may include first and second transistor sides spaced on opposite sides of the junction field-effect transistor neck region, such that the trench Schottky barrier diode may be located between the first and second transistor sides.

### RELATED APPLICATION

The present U.S. non-provisional patent application is related to and claims priority benefit of an earlier-filed U.S. provisional patent application titled “Planar MOSFET with Integrated Trench Schottky Barrier Diode and Methods to Manufacture Same,” Ser. No. 63/730,292, filed Dec. 10, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern an apparatus including an integrated planar metal oxide semiconductor field-effect transistor and an integrated planar Schottky barrier diode, and a method of making an apparatus including an integrated planar metal oxide semiconductor field-effect transistor and an integrated planar Schottky barrier diode.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide an apparatus including an integrated planar MOSFET and an integrated planar Schottky barrier diode (SBD), and a method of making an apparatus including an integrated planar MOSFET and an integrated planar SBD. Broadly, the integrated SBD may be located over a junction field-effect transistor (JFET) neck region within a trench that is located between first and second sides of the integrated MOSFET, such that the MOSFET and the SBD are fully physically and functionally integrated into the apparatus, and are not discrete devices connected together. Examples advantageously improve reverse conduction by avoiding bipolar degradation when the parasitic P-N body diode is opened, and advantageously provide a much lower gate-drain capacitance (Cgd) while using less space, lowering switching losses, lowering cost, and requiring fewer dies in the manufacturing process.

In an example, semiconductor device may include a volume of semiconductor material, an integrated planar MOSFET, a JFET neck region, and an integrated SBD located within a trench defined in the volume of the semiconductor material (such that the SBD may be considered “an integrated trench SBD”). The volume of semiconductor material may include a first end, a second end spaced vertically from the first end, a first side, and a second side spaced laterally from the first side. The integrated planar MOSFET may include a first transistor side located at (which shall be interpreted herein to mean functionally adjacent (to thereby encompass physically adjacent or near)) the first side of the volume of semiconductor material. The first transistor side may include a first well located at the first end of the volume of semiconductor material, and a first gate. The JFET neck region of the volume of semiconductor material may be located adjacent to and spaced from the first transistor side. The trench may extend from the first end of the volume of semiconductor material. The trench may be located over at least a portion of the JFET neck region adjacent to and spaced from the first transistor side. The integrated SBD may comprise a Schottky material located within the trench.

The trench may include a base/bottom and a pair of sides extending between the base and the first end of the volume of semiconductor material. The Schottky material may line the base and sides of the trench.

The preceding example may include any one or more of the following features.

The integrated planar MOSFET may include a second transistor side that is located at/near the second side of the volume of semiconductor material, such that both the JFET neck region and the trench are located between and spaced from each of the first and second transistor sides. The second transistor side may include a second gate and a second well. The second well may be located at the first end of the volume of semiconductor material.

Each of the first and second transistor sides may include additional sub-components. For instance, the first transistor side may further include: a first source located above and adjacent to the first well, a first drain located at the second end of the volume of semiconductor material, and a first channel extending through the volume of semiconductor material between the first source and the first drain. Additionally, the second transistor side may further include: a second source located above and adjacent to the second well, a second drain located at the second end of the volume of semiconductor material, and a second channel extending through the volume of semiconductor material between the second source and the second drain.

According to various examples of the present disclosure, each well may include a P-type material, each source may include an N+ material, and each drain may include an N+ material.

In various examples of the present disclosure, the Schottky material used to line the trench may be selected from the group consisting of: titanium, molybdenum, platinum, chromium, aluminum, tungsten, and combinations thereof.

In various examples of the present disclosure, each of the first and second gate may include a layer of dielectric material located over at least a portion of the respective first or second well along, with a layer of polysilicon over the layer of dielectric material.

In various examples of the present disclosure, the layer of dielectric material may extend over at least a portion of the respective first or second source and a portion of the JFET neck region of the semiconductor device.

In another example, a semiconductor device may include a volume of semiconductor material, an integrated planar MOSFET, a JFET neck region, and an integrated trench SBD. The volume of semiconductor material may include a first end, a second end spaced vertically from the first end, a first side, and a second side spaced laterally from the first side. The integrated planar MOSFET may include a first transistor side and a second transistor side. The first transistor side may be located at the first side of the volume of semiconductor material. The first transistor side may include a first well located at the first end of the volume of semiconductor material, and a first gate. Similarly, the second transistor side may be located at the second side of the volume of semiconductor material. The second transistor side may include a second well located at the first end of the volume of semiconductor material, and a second gate. Each of the first and second gates may include a layer of dielectric material located over at least a portion of the respective first or second well, and a layer of polysilicon over the layer of dielectric material. The JFET neck region of the volume of semiconductor material may be located between the first transistor side and the second transistor side. The trench may extend from the first end of the volume of semiconductor material, with the trench being over at least a portion of the JFET neck region and adjacent to and spaced laterally apart from the first and second transistor sides. The trench may include a base and a pair of sides extending between the base and the first end of the volume of semiconductor material. The integrated SBD may include a Schottky material lining the base and the sides of the trench.

The preceding example may further include any one or more of the following features. The first transistor side may further include: a first source located above and adjacent to the first well, a first drain located at the second end of the volume of semiconductor material, and a channel extending through the volume of semiconductor material between the first source and the first drain. Similarly, the second transistor side may further include: a second source located above and adjacent to the second well, a second drain located at the second end of the volume of semiconductor material, and a second channel extending through the volume of semiconductor material between the second source and the second drain. Each of the first and second well may be or at least partially include a P material, each of the first and second source may be or at least partially include an N+ material, and each of the first and second drain may be or at least partially include an N+ material. The Schottky material may be selected from the group consisting of: titanium, molybdenum, platinum, chromium, aluminum, tungsten, and combinations thereof. The layer of dielectric material included in each of the first and second gate may extend over at least a portion of the respective first or second source and a portion of the JFET neck region.

In yet another example, a method may include the following operations. A volume of semiconductor material may be grown to include a first end, a second end spaced vertically from the first end, a first side, and a second side spaced laterally from the first side, and including a JFET neck region. A first transistor side of an integrated planar MOSFET may be formed at the first side of the volume of semiconductor material and adjacent to the JFET neck region. A trench may be formed at the first end of the volume of semiconductor material over at least a portion of the JFET neck region and spaced apart from the first transistor side of the integrated planar MOSFET. An integrated SBD may be formed within the trench, e.g., by placing a Schottky material within the trench.

The method of the preceding example may further include any one or more of the following operations and/or features. The operation of placing the Schottky material within the trench may include the step of lining a base and sides of the trench with the Schottky material. The method may further include forming a second transistor side of the integrated planar MOSFET at the second side of the volume of semiconductor material, such that the JFET neck region and the trench are each located between and spaced apart from the first and second transistor sides. The operation of forming the first transistor side may further include: implanting a first P-well at or near the first end of the volume of semiconductor material, forming a first gate, implanting a first N+ source above and adjacent to the first P-well, providing a first N+ drain at the second end of the volume of semiconductor material, wherein the volume of semiconductor material between the first source and the first drain provides a first channel. The operation of forming the second transistor side may further include: implanting a second P-well at or near the first end of the volume of semiconductor material, forming a second gate, implanting a second N+ source above and adjacent to the second P-well, providing a second N+ drain at the second end of the volume of semiconductor material, wherein the volume of semiconductor material between the second source and the second drain provides a second channel. The operation of forming each of the first and second gates may include providing a layer of dielectric material over at least a portion of the respective first or second well, and depositing a layer of polysilicon over the layer of dielectric material. The operation of providing the layer of dielectric material may include the steps of positioning the layer of dielectric material over at least a portion of the respective first or second source and a portion of the JFET neck region. The Schottky material may be selected from a group consisting of: titanium, molybdenum, platinum, chromium, aluminum, tungsten, and combinations thereof.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example semiconductor device including an integrated planar MOSFET and an integrated trench SBD, wherein the integrated trench SBD is located between first and second sides of the integrated planar MOSFET;

FIG. 2 is a cross-sectional elevation view of a semiconductor device including an integrated trench SBD, such as the semiconductor device of FIG. 1, including additional details on the trench; and

FIG. 3 is flowchart of operations in an example of a method of making a semiconductor device including an integrated planar MOSFET and an integrated trench SBD, wherein the integrated SBD.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Furthermore, the use of the term “vertical” herein is to be understood as generally defining a direction between the first and second ends of the volume of semiconductor material. For example, it should be understood that a component or element described as extending vertically shall mean the component or element extends at least primarily in the vertical direction (e.g., in an orthogonal direction relative to the first end of the volume of semiconductor material, even if true orthogonality is not maintained over the entire span of the component or element). Similarly, the use of the term “lateral” herein is to be understood to as generally defining a direction between the first and second sides of the volume of semiconductor material. For example, a “lateral” component or element will be understood to extend at least primarily in the horizontal direction (e.g., in a parallel direction relative to the first end of the volume of semiconductor material, even if true parallelism is not maintained over the entire span the component or element).

Thus, it will be readily understood that the components of the examples as generally described herein and illustrated in the drawings could be arranged and designed in a wide variety of different configurations. The following description of various examples is consequently not intended to limit the scope of the present disclosure but is merely representative of various examples.

Examples provide an apparatus including an integrated planar MOSFET and an integrated planar SBD, and a method of making an apparatus including an integrated planar MOSFET and an integrated planar SBD. Broadly, the integrated SBD may be located over a JFET neck region, such that the MOSFET and the SBD are fully physically and functionally integrated into the apparatus, and are not discrete devices connected together.

The improved reverse conduction (i.e., the third quadrant performance) of a MOSFET (particularly a MOSFET including silicon carbide (SiC) semiconductor material) is desirable for next-generation compact power electronics. Integration of the SBD with the MOSFET provides an efficient mechanism for avoiding bipolar degradation when the parasitic P-N body diode is opened. If the forward voltage of the body diode of the MOSFET is three and one-half (3.5) volts (V), and the forward voltage of the SBD is one and one-half (1.5) V, then the forward voltage drop is reduced by two (2) V, resulting in lower forward voltage losses. Further, integrating the SBD in this manner provides a much lower Cgd. Additionally, integrating the SBD rather than connecting a discrete SBD provides the advantages of using less space, lowering switching losses, lowering cost, and requiring fewer dies in the manufacturing process.

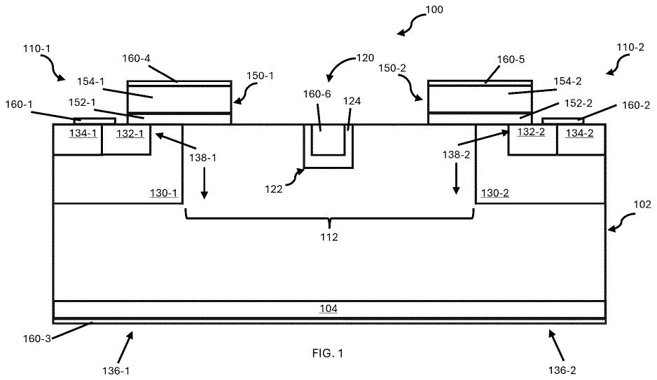

Referring to FIG. 1, an example of a semiconductor device 100 including an integrated planar MOSFET 110 and an integrated trench SBD 120 is shown. Broadly, the semiconductor 100 may include a volume of semiconductor material 102, a substrate material 104, the integrated planar MOSFET 110, a JFET neck region 112, and the integrated trench SBD 120.

The volume of semiconductor material 102 may include a first end, a second end spaced vertically from the first end, a first side, and a second side spaced laterally from the first side. The volume of semiconductor material 102 may be constructed from or include an N-type epitaxial semiconductor material. The substrate material 104 may be located at the second end of the volume of semiconductor material 102, and may be constructed from or include an N+ substrate material or doped to be an N+ material.

The integrated planar MOSFET 110 may include a first MOSFET or transistor side 110-1 located at the first side of the volume of semiconductor material 102 and a second MOSFET or transistor side 110-2 located at the second side of the volume of semiconductor material 102. The JFET neck region 112 may be a region of the volume of semiconductor material 102 located between the first and second MOSFET sides 110-1, 110-2. More specifically, the integrated trench SBD 120 may be located at the first end of the volume of semiconductor material 102 over at least a portion of the JFET neck region 112 adjacent to and spaced apart from each of the first and second MOSFET sides 110-1, 110-2.

The integrated MOSFET 110 may be a silicon carbide (SiC) MOSFET. The first and second MOSFET sides 110-1, 110-2 may include respective first and second regions or sub-volumes of the volume of semiconductor material 102. Thus, the volume of semiconductor material 102 may be a single, physically continuous structure that is shared by the first and second MOSFET sides 110-1, and 110-2 and the integrated trench SBD 120. The first and second MOSFET sides 110-1, 110-2 may further include respective first and second portions of the substrate material 104. The first and second MOSFET sides 110-1, 110-2 may further include respective first and second instances of various structures and associated materials. Generally, the first and second MOSFET sides 110-1, 110-2 may be mirror-images or “flipped” versions (i.e., flipped horizontally about the JFET neck region 112) of each other—i.e., some or all of the respective structures and associated materials may be reversed in order or position on opposite sides of the shared JFET neck region 112. According to some aspects of the example apparatus, some structural and/or material variations between the transistor sides 110-1, 110-2 may be permissible.

The first and second instances of the various structures and materials of the first and second MOSFET sides 110-1, 110-2 may be implanted (using, e.g., an ion implanter), deposited, or otherwise provided using a suitable technique in or on the respective sub-volumes of the volume semiconductor material 102. These structures and materials and their sizes and positions may vary, but may generally include the following. First and second wells 130-1, 130-2 may be constructed from or include a P+ material. The first well 130-1 may be located at the first side and the first end of the volume of semiconductor material 102. The second well 130-2 may be located at the second side and first end of the volume of semiconductor material 102. First and second sources 132-1, 132-2 may be constructed from or include an N+ material, and may be located above at least a portion of and adjacent to the respective first and second well 130-1, 130-2. First and second body contacts 134-1, 134-2 may be constructed from or include a P+ material, and may be located adjacent to the respective first and second sources 132-1, 132-2 and above a portion of the respective first and second wells 130-1 and 130-2. First and second drains 136-1, 136-2 may be provided by respective portions of the N+ substrate 104, and be located on their respective transistor side 110-1, 110-2 of the integrated planar MOSFET 110. (It will be appreciated by those of ordinary skill in the art that the substate 104 provides a common drain, although portions thereof are described herein as being associated with respective sides of the MOSFET 110.) A first and second channel 138-1, 138-2 may extend through the volume of semiconductor material 102 between the respective first and second source 132-1, 132-2 and the respective first and second drain 136-1, 136-2. Majority charge carriers included in the semiconductor device 100 may move, and any current resulting therefrom may flow through the channel(s) 138-1, 138-2.

First and second transistor sides 110-1, 110-2 may include a first and second gate 150-1, 150-2, respectively. First and second layers of dielectric material 152-1, 152-2, or gate oxide (e.g., silicon oxide [SiO₂]), may be provided over a portion of respective sides of the JFET neck region 112, and covering at least a portion the respective first and second wells 130-1, 130-2. As depicted in FIG. 1, the first and second layers of dielectric material 152-1, 152-2 may be located over at least a portion of first and second sources 132-1, 132-2. Further, also seen in FIG. 1, no dielectric material is provided over a center portion of the JFET neck region 112 between the first and second transistor sides 110-1, 110-2, or over the integrated trench SBD 120.

First and second of structures of a polysilicon material 154-1, 154-2 may be located over the respective first and second layers of dielectric material 152-1, 152-2. The polysilicon structure may be constructed from or include a P-type polysilicon material, or doped to be a P-type polysilicon material. The layers of dielectric material 152-1, 152-2 and structures of polysilicon material 154-1, 154-2 cooperatively form respective first and second gates 150-1, 150-2, each of the first and second gates 150-1, 150-2 corresponding with one of the MOSFET sides 110-1, 110-2. Alternative gate constructions may be within the ambit of the example apparatus. As seen in FIG. 1, the example MOSFET includes no polysilicon or oxide over the center portion of the JFET neck region 112 between the first and second MOSFET sides 110-1, 110-2. Thus, the first and second gates 150-1, 150-2 may be located on either side of the JFET neck region 112 (providing the semiconductor device 100 is of a so-called “split gate design). Although the illustrated MOSFET 110 includes a split gate configuration, according to certain examples, the first and second gates 150-1, 150-2 may be shorted such that an electrically common gate is provided.

It will be appreciated that the example semiconductor device 100 is an N-channel MOSFET. However, certain aspects of the example semiconductor device 100 might be applicable to P-channel MOSFETs.

A trench 122 may be provided in the volume of semiconductor material, and the integrated trench SBD 120 may be located in the trench 122. The trench 122 may be located over a portion of the JFET neck region 112 that is at the first end of the volume of semiconductor material 102 and between the first and second MOSFET sides 110-1, 110-2. The integrated trench SBD 120 may include a Schottky material 124, and may be formed by, e.g., lining, filling, or otherwise providing the trench 122 with the Schottky material 124. The Schottky material 124 may be a metal such as titanium, molybdenum, platinum, chromium, tungsten, or combinations thereof.

The semiconductor device 100 may further include electrical terminals 160-1 through 160-6 to facilitate applying appropriate electrical voltages, which are discussed below. More specifically, first and second electrical terminals 160-1, 160-2, may be added to the respective first and second sources 132-1, 132-2 and body contacts 132-1 and 134-2 (with the first and second terminals 160-4, 160-5 being a common terminal or otherwise shorted, according to certain examples), a single third electrical terminal 160-3 may be added that spans the first and second drains 136-1, 136-2, fourth and fifth electrical terminals 160-4, 160-5 may be added to the respective first and second gates 150-1, 150-2 (with the fourth and fifth terminals 160-4, 160-5 being a common terminal or otherwise shorted, according to certain examples), and a sixth electrical terminal 160-6 may be added to the integrated trench SBD 120.

In operation, when a voltage, Vgs, is applied between the source 132-1, 132-2 and the first and second gates 150-1, 150-2, the generated electric field creates an inversion layer at the semiconductor-dielectric interface. The inversion layer provides the first and second channels 138-1, 138-2 through which electrical current can flow when another voltage, Vds, is applied between one or more of the first and second sources 132-1, 132-2 and the first and second drain 136-1, 136-2. More specifically, a gate-source voltage, or Vgs, controls the width of the depletion region at the P-N junction where the charge carriers of the P- and N-type materials diffuse into each other, which “depletes” the available concentrations of majority charge carrier in each material, and thereby controls the current, Id, from the drains 136-1, 136-2 to the sources 132-1, 132-2. In the present examples, the integrated trench SBD 120 improves reverse conduction by avoiding bipolar degradation when the parasitic P-N body diode is opened, and provides a much lower gate-drain capacitance, Cgd.

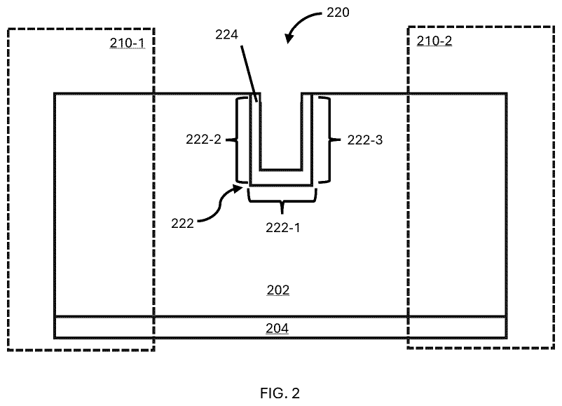

Referring to FIG. 2, an example of a volume of semiconductor material 202 grown, e.g., epitaxially, on a substrate material 204 and including an integrated trench SBD 220 is shown. Each of the volume of semiconductor material 202, the substrate material 204, and the integrated trench SBD 220 may be substantially similar and/or identical to the equivalent structure depicted in FIG. 1 (e.g., the volume of semiconductor material 102, the substrate material 104, and the integrated trench SBD 120, respectively).

Etching may be used to form the trench 222 in which the integrated trench SBD 220 is located. As illustrated, the trench 222 is located in the first end of the volume of semiconductor material 202, between a first and second sub-volume 210-1, 210-2. In various examples, each of the first and second sub-volumes 210-1, 210-2 may include a respective first and second side of a single semiconductor device, such as a MOSFET, that is integrated into the volume of semiconductor material 202 (e.g., the first and second transistor sides 110-1, 110-2 of the integrated planar MOSFET 110 depicted in FIG. 1).

The trench 222 includes a base 222-1 and a pair of sides 222-2, 222-3 extending between the base 222-1 and the first end of the volume of semiconductor material 202. In various examples, the base 222-1 (having a lateral width, ‘b’) and sides 222-2, 222-3 (each having a vertical height, ‘h’) of the trench 222 may be lined with a Schottky material 224 to form the integrated trench SBD 220.

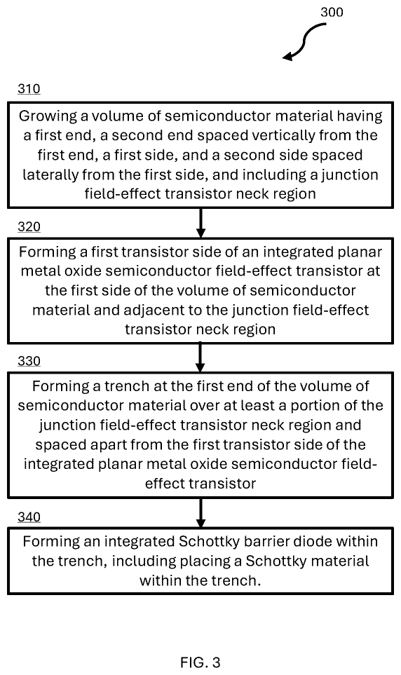

Referring to FIG. 3, a method 300 of making a semiconductor device including an integrated planar MOSFET and an integrated trench SBD. Unless expressly stated otherwise herein or as may be understood by those of ordinary skill in the art, the steps may be performed in the order shown in FIG. 3, or the steps may be performed in a different order. Furthermore, some steps may be performed concurrently as opposed to sequentially. In addition, some steps may be optional.

At operation 310, a volume of semiconductor material (e.g., the volume of semiconductor material 102 of FIG. 1 and/or the volume of semiconductor material 202 of FIG. 2) may be formed to present a first end, a second end spaced vertically from the first end, a first side, and a second side spaced laterally from the first side, and including a JFET neck region (e.g., the JFET neck region 112 of FIG. 1). The volume of semiconductor material may, for example, be grown via epitaxy on a substrate/substrate material (e.g., the substrate material 104 of FIG. 1 and/or the substrate material 204 of FIG. 2). The substrate material may also be grown epitaxially or otherwise provided. In various examples, the volume of semiconductor material may be an N-type material, and the substrate material may be an N+ material.

At operation 320, a first transistor side (e.g., the first transistor side 110-1 of FIG. 1) of an integrated planar MOSFET (e.g., the integrated planar MOSFET 110 of FIG. 1) may be formed at the first side of the volume of semiconductor material and adjacent to the JFET neck region. Forming the first transistor side may further include forming or otherwise providing each of the following: a first well at the first end of the volume of semiconductor material, a first gate, a first source above and adjacent to the first well, and a drain located at the second end of the volume of semiconductor material. According to the present disclosure: each of the first well and the first source may be implanted, e.g., via ion implantation; the drain, which may be included in/a segment of the substrate material, may be grown epitaxially or otherwise provided, e.g., before the remainder of the volume of semiconductor material is grown or otherwise formed, as explained above; and the first gate may be formed via (i) growing (e.g., via thermal oxidation), depositing, or otherwise providing a layer of dielectric material (e.g., gate oxide) over at least a portion of the first well and over, a portion of the JFET neck region, and a portion of the source, and (ii) depositing or otherwise providing a layer of polysilicon over the layer of dielectric material. The first well may be a P-type material, each of the first source and the first drain may be an N+ material, the gate oxide material will ideally be of neutral charge but practically is likely to be slightly charged due to material impurities that exist naturally and that are introduced during manufacturing processes, and the polysilicon may be doped to specification.

At operation 330, a trench, such as the trench 122 of FIG. 1 or the trench 222 of FIG. 2, may be formed. According to the present disclosure, the trench 330 may be formed at the first end of the volume of semiconductor material over at least a portion of the JFET neck region. The trench 330 is formed so as to be spaced apart from the first transistor side of the integrated planar MOSFET. In various examples, the trench may be formed via etching, and the resulting trench may include a base and a pair of sides extending from the base to the top of the first end of the volume of semiconductor material. While the trenches 122, 222 depicted in FIGS. 1 and 2, each have sides that are symmetric, straight and parallel relative to each other, and perpendicular to the base of the trench and the top of the first end of the volume of semiconductor material, it is to be understood that other shapes and relationships between the sides, the base, and the top of the first end of the volume of semiconductor materials are within the ambit of the present disclosure.

At operation 340, an integrated (trench) SBD may be formed within the trench, e.g., by placing a Schottky material within the trench. In some examples, the Schottky material may line the base and sides of the trench. In other examples, the Schottky material may completely fill or otherwise located at least in part within the trench. According to the present disclosure, the Schottky material may be selected from the group consisting of: titanium, molybdenum, platinum, chromium, aluminum, tungsten, and combinations thereof. The Schottky material may be grown epitaxially within the trench, deposited into the trench, or otherwise provided.

The method 300 of forming a semiconductor device including an integrated planar MOSFET may further include forming a second transistor side (e.g., the second transistor side 110-2 of FIG. 1) at the second side of the volume of semiconductor material. As described above, the second transistor side may be a “mirrored” or “flipped” version of the first transistor side. Therefore, a “second” version of each of the structures/sub-components included in the first transistor side may be included in the second transistor side which, in accordance with the present disclosure, may be (i) formed in a manner that is substantially the same/identical to how the “first” versions of said structures/sub-components were formed (as described above), and (ii) may be of substantially the same/identical material composition(s) as the “first” versions of said structures/sub-components (as described above). However, it is to be understood that deviations in geometry and material composition between each of the respective “first” and “second” structures/sub-components included the first and second transistor sides are within the scope of the present disclosure.

Additional processing may be performed as desired.

Although described herein with regard or in relation to one or more particular kinds of electronic devices (e.g., metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, unless otherwise specified or unless one with ordinary skill in the art would understand otherwise, the gate material may include polysilicon, a metal or alloy of metals, or other suitable material; and the semiconductor material may include silicon carbide, silicon, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be similarly or alternatively constructed to the illustrated device 100 or may be entirely different devices providing different operations or functions than the illustrated device 100. In other words, in practice, the illustrated device 100 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations for contact implants may be approximately between ten to the power of eighteen (10\hat{ }18) and ten to the power of twenty two (10\hat{ }22); doping concentrations for channel and threshold forming implants may be approximately between ten to the power of sixteen (10\hat{ }16) and ten to the power of seventeen (10\hat{ }17); doping concentrations for shielding implants may be approximately between ten to the power of seventeen (10\hat{ }17) and ten to the power of nineteen (10\hat{ }19); and doping concentrations for conductivity improvement implants (e.g., N-doping in the junction field-effect transistor neck region of a metal oxide semiconductor field-effect transistor) may be approximately between ten to the power of sixteen (10\hat{ }16) and ten to the power of seventeen (10\hat{ }17). Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additional, deletions, and modifications to the illustrated and described examples may be made without departing from the scope of the disclosure as hereinafter claimed along with their legal equivalents. In addition, features from one example may be combined with features of another example(s) while still being encompassed within the scope of the disclosure as contemplated by the inventors.

What is claimed is:

1. A semiconductor device comprising:
a volume of semiconductor material including a first end, a second end spaced vertically from the first end, a first side, and a second side spaced laterally from the first side;
an integrated planar metal oxide semiconductor field-effect transistor including a first transistor side located at the first side of the volume of semiconductor material, the first transistor side including:
a first well located at the first end of the volume of semiconductor material, and a first gate;
a junction field-effect transistor neck region of the volume of semiconductor material located adjacent to the first transistor side; and
a trench extending from the first end of the volume of semiconductor material, with the trench being over at least a portion of the junction field-effect transistor neck region and adjacent to and spaced from the first transistor side; and
an integrated Schottky barrier diode comprising a Schottky material located within the trench.

2. The semiconductor device of claim 1,
the trench including a base and a pair of sides extending between the base and the first end of the volume of semiconductor material,
the Schottky material lining the base and the sides of the trench.

3. The semiconductor device of claim 1, wherein the integrated planar metal oxide semiconductor field-effect transistor further includes a second transistor side located at the second side of the volume of semiconductor material, wherein the junction field-effect transistor neck region and the trench are located between and spaced from the first and second transistor sides, the second transistor side including:
a second well located at the first end of the volume of semiconductor material, and
a second gate.

4. The semiconductor device of claim 3,
wherein the first transistor side further includes:
a first source located above and adjacent to the first well,
a first drain located at the second end of the volume of semiconductor material, and
a first channel extending through the volume of semiconductor material between the first source and the first drain,
wherein the second transistor side further includes:
a second source located above and adjacent to the second well,
a second drain located at the second end of the volume of semiconductor material, and
a second channel extending through the volume of semiconductor material between the second source and the second drain.

5. The semiconductor device of claim 4,
each well including a P material,
each source including an N+ material,
each drain including an N+ material.

6. The semiconductor device of claim 3,
each of the first and second gates including:
a layer of dielectric material located over at least a portion of the respective first or second well, and
a layer of polysilicon over the layer of dielectric material.

7. The semiconductor device of claim 6, wherein the layer of dielectric material extends over at least a portion of the respective first or second source and a portion of the junction field-effect transistor neck region.

8. The semiconductor device of claim 1, wherein the Schottky material is selected from the group consisting of: titanium, molybdenum, platinum, chromium, aluminum, tungsten, and combinations thereof.

9. A semiconductor device comprising:
a volume of semiconductor material including a first end, a second end spaced vertically from the first end, a first side, and a second side spaced laterally from the first side;
an integrated planar metal oxide semiconductor field-effect transistor including—
a first transistor side located at the first side of the volume of the semiconductor material, the first transistor side including—
a first well located at the first end of the volume of semiconductor material, and
a first gate, and
a second transistor side located at the second end of the volume of semiconductor material, the second transistor side including—
a second well located at the first end of the volume of semiconductor material, and
a second gate,
each of the first and second gates including:
a layer of dielectric material located over at least a portion of the respective first or second well, and
a layer of polysilicon over the layer of dielectric material,
a junction field effect transistor neck region of the volume of semiconductor material located between the first transistor side and the second transistor side;
a trench extending from the first end of the volume of semiconductor material, with the trench being over at least a portion of the junction field-effect transistor neck region and adjacent to and spaced laterally from each of the first and second transistor sides,
the trench including a base and a pair of sides extending between the base and the first end of the volume of semiconductor material; and
an integrated Schottky barrier diode comprising a Schottky material lining the base and the sides of the trench.

10. The semiconductor device of claim 9,
wherein the first transistor side further includes—
a first source located above and adjacent to the first well,
a first drain located at the second end of the volume of semiconductor material, and
a first channel extending through the volume of semiconductor material between the first source and the first drain, and
wherein the second transistor side further includes—
a second source located above and adjacent to the second well,
a second drain located at the second end of the volume of semiconductor material, and
a second channel extending through the volume of semiconductor material between the second source and the second drain.

11. The semiconductor device of claim 10,
each well including a P material,
each source including an N+ material,
each drain including an N+ material.

12. The semiconductor device of claim 9, wherein the Schottky material is selected from the group consisting of: titanium, molybdenum, platinum, chromium, aluminum, tungsten, and combinations thereof.

13. The semiconductor device of claim 9, wherein the layer of dielectric material extends over at least a portion of the respective first or second source and a portion of the junction field-effect transistor neck region.

14. A method comprising:
growing a volume of semiconductor material including a first end, a second end spaced vertically from the first end, a first side, and a second side spaced laterally from the first side, and including a junction field-effect transistor neck region;
forming a first transistor side of an integrated planar metal oxide semiconductor field-effect transistor at the first side of the volume of semiconductor material and adjacent to the junction field-effect transistor neck region;
forming a trench at the first end of the volume of semiconductor material over at least a portion of the junction field-effect transistor neck region and spaced apart from the first transistor side of the integrated planar metal oxide semiconductor field-effect transistor; and
forming an integrated Schottky barrier diode within the trench, including placing a Schottky material within the trench.

15. The method of claim 14, wherein the trench includes a base and a pair of sides extending between the base and the first end of the volume of semiconductor material,
the operation of placing the Schottky material within the trench includes the step of lining the base and the sides of the trench.

16. The method of claim 14, further comprising—
forming a second transistor side of the integrated planar metal oxide semiconductor field-effect transistor at the second side of the volume of semiconductor material, such that the junction field-effect transistor neck region and the trench are located between and spaced from the first and second transistor sides.

17. The method of claim 16,
said operation of forming the first transistor side further including—
implanting a first P-well at the first end of the volume of semiconductor material,
forming a first gate,
implanting a first N+ source above and adjacent to the first P-well,
a first N+ drain at the second end of the volume of semiconductor material,
wherein the volume of semiconductor material between the first source and the first drain provides a first channel.
said operation of forming the second transistor side further including—
implanting a second P-well at the first end of the volume of semiconductor material,
forming a second gate,
implanting a second N+ source above and adjacent to the second P-well,
providing a second N+ drain at the second end of the volume of semiconductor material,
wherein the volume of semiconductor material between the second source and the second drain provides a second channel.

18. The method of claim 17,
the operation of forming each of the first and second gates including:
providing a layer of dielectric material over at least a portion of the respective first or second well, and
depositing a layer of polysilicon over the layer of dielectric material.

19. The method of claim 18,
the operation of providing the layer of dielectric material includes the step of positioning the layer of dielectric material over at least a portion of the respective first or second source and a portion of the junction field-effect transistor neck region.

20. The method of claim 14, wherein the Schottky material is selected from a group consisting of: titanium, molybdenum, platinum, chromium, aluminum, tungsten, and combinations thereof.
